(19) United States
(12) Patent Application Publication
(10) Pub. No.: US 2012/0112198 A1
(43) Pub. Date: May 10, 2012

(54) EPITAXIAL GROWTH OF SILICON CARBIDE ON SAPPHIRE

(75) Inventors: Jack O. Chu, Manhasset Hills, NY (US); Christos D. Dimitrakopoulos, Baldwin Place, NY (US); Alfred Grill, White Plains, NY (US); Timothy J. McArdle, Mahopac, NY (US); Katherine L. Saenger, Ossining, NY (US); Robert L. Wisnieff, Ridgefield, CT (US); Yu Zhu, West Harrison, NY (US)

(73) Assignee: INTERNATIONAL BUSINESS MACHINES CORPORATION, Armonk, NY (US)

(21) Appl. No.: 12/942,498

(22) Filed: Nov. 9, 2010

(51) Int. Cl. H01L 29/04; H01L 29/24; C30B 25/18

(52) U.S. Cl. 257/64; 117/104; 257/77; 257/E29.104; 257/E29.004

(57) ABSTRACT

remove impurities from an exposed surface in the ultrahigh vacuum environment. A high qualify single crystalline or polycrystalline silicon carbide film can be grown directly on the sapphire substrate by chemical vapor deposition employing a silicon-containing reactant and a carbon-containing reactant. Formation of single crystalline silicon carbide has been verified by x-ray diffraction, secondary ion mass spectroscopy, and transmission electron microscopy.

### RELATED APPLICATIONS

The present application is related to co-assigned and co-pending U.S. application Ser. Nos. 12/844,029 filed on Jul. 27, 2010 and (Attorney Docket No: YOR920100055US1; SSMP 24972 being filed on the same date herewith).

### STATEMENT REGARDING FEDERALLY SPONSORED RESEARCH OR DEVELOPMENT

This invention was made with government support under Defense Advanced Research Project Agency (DARPA) CERA Contract No. FA8650-08-C-7838 awarded by the U.S. Department of Defense. The government has certain rights in this invention.

### BACKGROUND

The present invention relates to a method of epitaxially depositing a silicon carbide layer on a sapphire substrate, and a structure obtained by the same.

Alpha silicon carbide has a hexagonal crystal structure, and beta silicon carbide has a cubic crystal structure of zinc blende type. FIG. 1 schematically shows the crystallographic structure of alpha silicon carbide. A (0001) surface is perpendicular to the c-axis and atoms in the (0001) surface are arranged in a pattern having a hexagonal symmetry. The plane in which the (0001) surface is located is referred to as a C plane. A (1102) surface of alpha silicon carbide crystal has a cubic symmetry, and does not have a hexagonal symmetry. The lack of hexagonal symmetry in the (1102) surface of silicon carbide has been considered a detriment to formation of any epitaxial hexagonal structure thereupon.

Silicon carbide substrates having a (0001) surface orientation are not commercially available at a diameter greater than 4 (or 5) inches at the present time. Such unavailability of silicon carbide (SiC) substrates currently makes it impossible to provide a 200 mm substrate or a 300 mm substrate containing a silicon carbide layer. Thus, formation of a single-crystalline silicon carbide layer on a substrate having a diameter of six inches or greater depends on the ability to deposit single crystalline silicon carbide material on a non-SiC single crystalline substrate by epitaxy.

In order to form a structure, such as a graphene layer, derived from a layer of silicon carbide on a substrate having a diameter of six inches or greater, the formation of a single crystalline silicon carbide material by heteroepitaxial growth on a large substrate is necessary. Graphene is a structure consisting of carbon as a two-dimensional sheet. Moreover, “graphene” as used herein denotes a one-atom thick planar sheet of sp²-bonded carbon atoms that are densely packed in a honeycomb crystal lattice. Graphene can be comprised of single-layer graphene (nominally 0.34 nm thick), few-layer graphene (2-10 graphene layers), multi-layer graphene (greater than 10 graphene layers), a mixture of single-layer, few layer, and multi-layer graphene, or any combination of graphene layers mixed with amorphous carbon (a-C) and/or disordered carbon phases. A disordered carbon phase may be, for example, a crystalline carbon phase with a high density of defects or a nanocrystalline carbon material.

Further, graphene provides excellent in-plane electrical conductivity and carrier mobility. Semiconductor devices employing graphene have been suggested in the art to provide high-density and high-switching-speed semiconductor circuits. Carbon atoms are arranged in a two-dimensional honeycomb crystal lattice in which each carbon-carbon bond has a length of about 0.142 nm. It is possible by using a similar heteroepitaxial growth method that a graphene layer may be grown by direct epitaxial deposition of carbon atoms on, i.e., addition of carbon atoms onto the surface of, a surface of a single crystalline silicon carbide (SiC) layer.

### BRIEF SUMMARY

Single crystalline and/or polycrystalline silicon carbide material is grown on a single crystalline sapphire substrate in an ultrahigh vacuum environment. The sapphire substrate is pretreated to remove impurities from an exposed surface in the ultrahigh vacuum environment. A high quality single crystalline or polycrystalline silicon carbide film can be grown directly on the sapphire substrate by chemical vapor deposition employing a silicon-containing reactant and a carbon-containing reactant. Formation of single crystalline silicon carbide has been verified by x-ray diffraction, secondary ion mass spectroscopy, and transmission electron microscopy.

According to an aspect of the present invention, a method of forming a semiconductor-carbon alloy layer on a sapphire substrate is provided. The method includes: placing a sapphire substrate in a vacuum environment; and providing a semiconductor-containing precursor and a carbon-containing precursor into the vacuum environment, wherein a single crystalline or polycrystalline semiconductor-carbon alloy layer is epitaxially formed directly on a crystallographic surface of the sapphire substrate.

According to another aspect of the present invention, a structure is provided, which includes a single crystalline or polycrystalline semiconductor-carbon alloy layer located directly on a crystallographic surface of a sapphire substrate.

### BRIEF DESCRIPTION OF THE SEVERAL VIEWS OF THE DRAWINGS

FIG. 1 is a diagram illustrating the crystallographic structure of alpha silicon carbide, which has a hexagonal crystal structure, and the orientations of a (0001) surface and a (1102) surface in relation to the hexagonal crystal structure.

FIG. 2 is a vertical cross-sectional view of a first exemplary structure including a single crystalline semiconductor-carbon alloy layer epitaxially deposited on a (0001) surface of a sapphire substrate and having a hexagonal crystal structure according to a first embodiment of the present invention.

FIG. 3 is a vertical cross-sectional view of a second exemplary structure including a single crystalline semiconductor-carbon alloy layer epitaxially deposited on a (1102) surface of a sapphire substrate and having a cubic crystal structure according to a second embodiment of the present invention.

FIG. 4 is a graph of x-ray diffraction (XRD) data from a sapphire substrate having a (0001) surface orientation before deposition of any single crystalline semiconductor-carbon alloy layer.

FIG. 5 is a graph of x-ray diffraction (XRD) data from a stack of a single crystalline semiconductor-carbon alloy layer having a hexagonal crystal structure and a (0001) surface orientation and a sapphire substrate having a (0001) surface orientation.

FIG. 6 is a magnified graph of x-ray diffraction (XRD) data of FIG. 5 for the 2θ range from 34 degrees to 37 degrees.

FIG. 7 is a graph of x-ray diffraction (XRD) data from a sapphire substrate having a (1102) surface orientation before deposition of any single crystalline semiconductor-carbon alloy layer.

FIG. 8 is a graph of x-ray diffraction (XRD) data from a stack comprising a single crystalline semiconductor-carbon alloy layer having a hexagonal crystal structure and a (001) surface orientation and a sapphire substrate having a (1102) surface orientation.

FIG. 9 is a magnified graph of x-ray diffraction (XRD) data of FIG. 8 for the 2θ range from 58 degrees to 62 degrees.

FIG. 10 is a graph of data from a secondary ion mass spectroscopy (SIMS) run on a single crystalline silicon carbide layer having a hexagonal crystal structure having a (0001) surface orientation that is epitaxially grown on a sapphire substrate having a (0001) surface orientation.

FIG. 11 is a transmission electron microscopy (TEM) image of an area of a sample including a stack of a single crystalline semiconductor-carbon alloy layer having a hexagonal crystal structure and a (001) surface orientation and a sapphire substrate having a (1102) surface orientation.

FIG. 12 is a transmission electron microscopy (TEM) image of another area of the sample of FIG. 11.

FIG. 13 is a high magnification transmission electron microscopy (TEM) image of an area of the sample of FIG. 11.

FIG. 14 is a Fourier transformation image of the silicon carbide area of the high magnification transmission electron microscopy (TEM) image of FIG. 13.

FIG. 15 is a Fourier transformation image of the sapphire area of the high magnification transmission electron microscopy (TEM) image of FIG. 13.

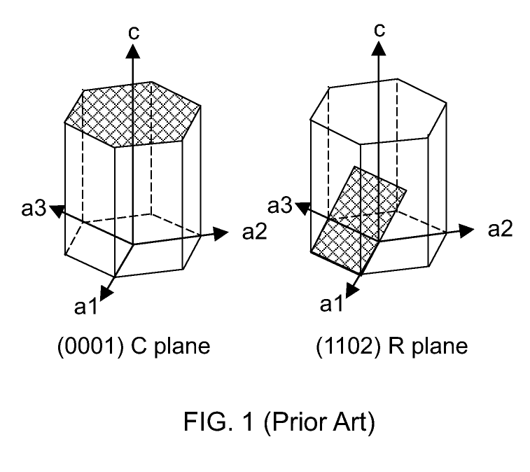

### DETAILED DESCRIPTION

As stated above, the present invention relates to a method of epitaxially depositing a silicon carbide layer on a sapphire substrate, and a structure obtained by the same, which are now described in detail with accompanying figures. It is noted that like and corresponding elements are referred to by like reference numerals. The drawings are not in scale. In drawings including a coordinate system, the x-axis is along a horizontal direction within the plane of the drawing, the y-axis is along a direction perpendicular to the plane of the drawing, and the z-axis is along a vertical direction within the plane of the drawing.

As used herein, an “ultrahigh vacuum” environment refers to a vacuum environment having a pressure less than 1.0×10⁻⁶ Ton.

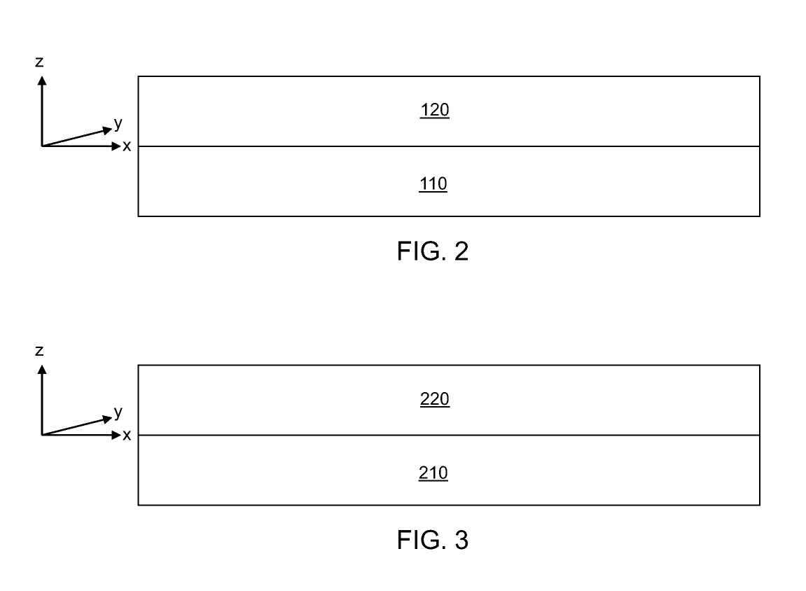

Referring to FIG. 2, a first exemplary structure including according to a first embodiment of the present invention includes a vertical stack of a single crystalline semiconductor-carbon alloy layer 120 and a sapphire substrate 110. The single crystalline semiconductor-carbon alloy layer 120 has a hexagonal crystal structure and a (0001) surface orientation. The single crystalline semiconductor-carbon alloy layer 120 is epitaxially deposited on a (0001) surface of the sapphire substrate 110.

It is noted that, by reducing the deposition temperature or by otherwise providing inferior growth conditions, for example, by providing an ambient including a significant level of residual gases within a deposition chamber, the single crystalline semiconductor-carbon alloy layer 120 can be replaced with a polycrystalline semiconductor-carbon alloy layer including at least one polycrystalline semiconductor-carbon alloy portions each having a hexagonal crystal structure and a (0001) surface orientation and epitaxially deposited on a (0001) surface of the sapphire substrate 110, while including grain boundaries between the various grains.

The sapphire substrate 110 consists essentially of aluminum oxide, i.e., Al₂O₃, and may include trace amounts of impurities at concentrations that do not affect the crystal structure of the sapphire substrate 110. The entirety of the sapphire substrate 110 is single crystalline. Sapphire substrates are currently commercially available at diameters up to 8 inches. The surface orientation of the sapphire substrate 110 is a (0001) orientation. The plane of the (0001) orientation is also referred to as a C plane.

The single crystalline semiconductor-carbon alloy layer 120 is a single crystalline layer in which all atoms are epitaxially aligned to all other atoms of the single crystalline semiconductor-carbon alloy layer 120 except for naturally present imperfections in the crystal lattice structure such as dislocations and/or point defects. Point defects can be substitutional defects or interstitial defects as known in the art.

The single crystalline semiconductor-carbon alloy layer 120 can be replaced with a polycrystalline semiconductor-carbon alloy layer including at least one polycrystalline semiconductor-carbon alloy portions. In the case of highly textured polycrystalline materials, high angle grain boundaries are typically observed.

In a first illustrative example, the single crystalline semiconductor-carbon alloy layer 120 can be a layer of a silicon-carbon alloy. Carbon has an atomic concentration from 20% to 75% in the silicon-carbon alloy, and preferably has an atomic composition from 45% to 55% in the silicon-carbon alloy. Alternately, a polycrystalline semiconductor-carbon alloy layer that is a layer of polycrystalline silicon-carbon alloy portions can be formed instead of the single crystalline semiconductor-carbon alloy layer 120.

In a second illustrative example, the single crystalline semiconductor-carbon alloy layer 120 can be a layer of a silicon-germanium-carbon alloy. Carbon has an atomic concentration from 20% to 75% in the silicon-germanium-carbon alloy, and preferably has an atomic composition from 45% to 55% in the silicon-germanium-carbon alloy. Alternately, a polycrystalline semiconductor-carbon alloy layer that is a layer of polycrystalline silicon-germanium-carbon alloy portions can be formed instead of the single crystalline semiconductor-carbon alloy layer 120.

In a third illustrative example, the single crystalline semiconductor-carbon alloy layer 120 can be a layer of a germanium-carbon alloy. Carbon has an atomic concentration from 20% to 75% in the germanium-carbon alloy, and preferably has an atomic composition from 45% to 55 in the germanium-carbon alloy. Alternately, a polycrystalline semiconductor-carbon alloy layer that is a layer of polycrystalline germanium-carbon alloy portions can be formed instead of the single crystalline semiconductor-carbon alloy layer 120.

In a fourth illustrative example, the single crystalline semiconductor-carbon alloy layer 120 can be a superlattice including multiple repetitions of a first material layer and a second material layer. At least one of the first material layer and a second material layer includes carbon, and at least one of the first material layer and a second material layer includes at least one of silicon and germanium. The first material layer may include silicon, germanium, or an alloy of silicon and the second material layer may include carbon or a carbon alloy. An exemplary combination of the first material layer and the second material layer is a silicon layer and a carbon layer. Another exemplary combination of the first material layer is a silicon boride layer and a carbon layer. Alternately, a polycrystalline semiconductor-carbon alloy layer that includes multiple repetitions of the first material layer and the second material layer can be formed instead of the single crystalline semiconductor-carbon alloy layer 120.

The single crystalline semiconductor-carbon alloy layer 120 is epitaxially deposited on the top surface of the sapphire substrate 110. Because the top surface of the sapphire substrate 110 has a hexagonal symmetry, which is the symmetry of the (0001) surface of a hexagonal crystal structure, the single crystalline semiconductor-carbon alloy layer 120 is formed with the same hexagonal crystal symmetry with a (0001) surface orientation, which also has a hexagonal symmetry, i.e., is invariant under rotation by 60 degrees along the z-axis that is perpendicular to the interface between the sapphire substrate 110 and the single crystalline semiconductor-carbon alloy layer 120. The single crystalline semiconductor-carbon alloy layer 120 can be a single crystalline semiconductor carbide layer such as a single crystalline silicon carbide layer. In this case, the single crystalline silicon carbide layer has alpha phase that has hexagonal crystal structure in which the surface orientation, i.e., the orientation of the x-y plane, is a (0001) orientation.

Referring to FIG. 3, a second exemplary structure including according to a second embodiment of the present invention includes a vertical stack of a single crystalline semiconductor-carbon alloy layer 220 and a sapphire substrate 210. The single crystalline semiconductor-carbon alloy layer 220 has a cubic crystal structure of zinc blende type and a (110) surface orientation. The single crystalline semiconductor-carbon alloy layer 220 is epitaxially deposited on a (1102) surface of the sapphire substrate 210.

The sapphire substrate 210 consists essentially of aluminum oxide as in the first embodiment. The entirety of the sapphire substrate 210 is single crystalline. However, the surface orientation of the sapphire substrate 210 is a (1102) orientation. The plane of the (1102) orientation is also referred to as an R plane.

The single crystalline semiconductor-carbon alloy layer 220 is a single crystalline layer in which all atoms are epitaxially aligned to all other atoms of the single crystalline semiconductor-carbon alloy layer 220 except for naturally present imperfections in the crystal lattice structure such as dislocations and/or point defects. Point defects can be substitutional defects or interstitial defects as known in the art. The composition of the single crystalline semiconductor-carbon alloy layer 220 can vary in the same manner as in the first embodiment.

The single crystalline semiconductor-carbon alloy layer 220 is epitaxially deposited on the top surface of the sapphire substrate 210. The top surface of the sapphire substrate 210 has a cubic symmetry, which is the symmetry of the (1102) surface of a hexagonal crystal structure. The single crystalline semiconductor-carbon alloy layer 220 is formed with cubic crystal symmetry with a (110) surface orientation, which has a rectangular symmetry, i.e., is invariant under rotation by 180 degrees along the z-axis that is perpendicular to the interface between the sapphire substrate 210 and the single crystalline semiconductor-carbon alloy layer 220. The single crystalline semiconductor-carbon alloy layer 220 can be a single crystalline semiconductor carbide layer such as a single crystalline silicon carbide layer. In this case, the single crystalline silicon carbide layer has beta phase that has cubic crystal structure of zinc blende type. The surface orientation, i.e., the orientation of the x-y plane, of the single crystalline semiconductor-carbon alloy layer 220 is a (110) orientation.

Single crystalline sapphire substrates of different crystallographic orientations are employed to form the first and second exemplary structures. To form the first exemplary structure, a single crystalline sapphire substrate having a (0001) surface orientation can be employed. To form the second exemplary structure, a single crystalline sapphire substrate having a (1102) surface orientation can be employed. The processing methods employed to form the first and second exemplary structures can be the same. Because identical processing steps can be employed for the first and second exemplary structures, each of the single crystalline sapphire substrate having a (0001) surface orientation and the single crystalline sapphire substrate having a (1102) surface orientation are herein referred to as a single crystalline sapphire substrate. The first exemplary structure can be eventually formed on the single crystalline sapphire substrate having a (0001) surface orientation, and the second exemplary structure can be eventually formed on the single crystalline sapphire substrate having a (1102) surface. The common processing steps are described below.

First, appropriate analysis can be performed before deposition of silicon carbide as needed on each single crystalline sapphire substrate, be it the single crystalline sapphire substrate having a (0001) surface orientation or the single crystalline sapphire substrate having a (1102) surface. For example, x-ray data on the sapphire substrates alone can be generated before any deposition on a single crystalline sapphire substrate. Subsequently, each sapphire substrate can be cleaned by chemical methods. Each single crystalline sapphire substrate can be cleaned employing a SC1 clean process in a solution including H₂O₂, NH₄OH, and H₂O. Thereafter, each single crystalline sapphire substrate can be cleaned employing a SC2 clean process in a solution including H₂O₂, HCl, and H₂O. The surface of each single crystalline sapphire substrate can be treated with dilute hydrofluoric acid to form a hydrogen-terminated surface. Isopropyl alcohol and/or nitrogen gas can be employed to dry the hydrogen-terminated surface without affecting the hydrogen-termination. Any equivalent surface clean that removes impurities from the surface of the sapphire substrate can also be employed.

The sapphire substrate can be subsequently placed in a vacuum environment. Specifically, after formation of the hydrogen-terminated surface, the sapphire substrate can be loaded in a process chamber, which can be then pumped down to a base pressure less than 5.0×10⁻⁸ Ton. Generally, the vacuum environment can be provided by an ultrahigh vacuum chamber having a base pressure less than 1.0×10⁻⁶ Ton. Each sapphire substrate can be then transferred to a process chamber, which can be maintained at a base pressure less than 2.0×10⁻⁸ Ton. While the transfer can be typically effected, for example, at a temperature from 300° C. to 800° C., the transfer can be effected at any operating temperature of the process chamber provided mechanical assemblies support a transfer at such a temperature.

The process chamber can be filled with hydrogen gas at a purge pressure, which can be, for example, between 0.1 mTorr to 100 mTorr, and typically from 1 mTorr to 10 mTorr. The temperature of the process chamber can be ramped to a deposition temperature, at which a subsequent deposition process is to be performed. Any other temperature ramp rate may be employed provided that the process chamber is capable of withstanding the rate of change in temperature without mechanical problems (such as component breakage). Any equivalent thermal surface clean can also be employed.

A semiconductor-containing precursor and a carbon-containing precursor can be provided into the vacuum environment so that a single crystalline semiconductor-carbon alloy layer is epitaxially formed directly on the crystallographic surface of the sapphire substrate. Specifically, after the hydrogen gas is shut off, the silicon-containing reactant gas and the carbon-containing reactant gas are flown into the process chamber simultaneously. The temperature of the process chamber can be maintained at a predetermined processing temperature, or can be ramped as needed to facilitate deposition. In general, the deposition temperature for the single crystalline semiconductor-carbon alloy layer can be from 800° C. to 2,000° C., and typically from 900° C. to 1,300° C., although lesser and greater deposition temperatures can also be employed. Further, depending on the composition and the desired deposition rate, the deposition temperature can be adjusted.

During the deposition step, the pressure in the process chamber can be maintained in a range from 0.1 mTorr to 100 mTorr, and typically from 1 mTorr to 10 mTorr, although lesser and greater deposition pressure can also be employed. The semiconductor-containing precursor includes the semiconductor component of a single crystalline semiconductor-carbon alloy layer, and the carbon-containing precursor includes carbon. Specifically, each molecule of the semiconductor-containing precursor includes a semiconductor atom or component atoms of a compound semiconductor material. Further, each molecule of the semiconductor-containing precursor includes at least one hydrogen atom, at least one chlorine atom, at least one fluorine atom, or a combination thereof. Each molecule of the carbon-containing precursor includes at least one unsaturated hydrocarbon atom.

The single crystalline semiconductor-carbon alloy layer can have an atomic carbon concentration consistent with a (0001) surface orientation during growth and a hexagonal crystal structure if deposited directly on a (0001) plane of a sapphire substrate. In this case, a (0001) surface of the single crystalline semiconductor-carbon alloy layer contacts a (0001) plane of the sapphire substrate at an interface. The single crystalline semiconductor-carbon alloy layer can have an atomic carbon concentration consistent with a (110) surface orientation during growth and a cubic crystal structure if deposited directly on a (1102) plane of a sapphire substrate. In this case, a (111) surface of the single crystalline semiconductor-carbon alloy layer contacts a (1102) plane of the sapphire substrate at an interface.

In case the single crystalline semiconductor-carbon alloy layer is a single crystalline silicon-carbon alloy layer, the semiconductor-containing precursor includes silicon. For example, the single crystalline semiconductor-carbon alloy layer can have an atomic carbon concentration consistent from 40% to 60%. The carbon-containing precursor can include carbon and hydrogen. In case the single crystalline semiconductor-carbon alloy layer is a single crystalline silicon-carbon alloy layer, the semiconductor-containing precursor can be selected from SiH₄, Si₂H₆, SiH₃Cl, SiH₂Cl₂, SiHCl₃, and SiCl₄. If the single crystalline semiconductor-carbon alloy layer includes germanium or a compound semiconductor in addition to silicon or in lieu of silicon, the semiconductor-containing precursor can be selected accordingly. The carbon-containing precursor can be selected from C₂H₂, C₂H₄, CₙH₂ₙ₋₂, and CₙH₂ₙ, wherein n is an integer greater than 2. If the single crystalline semiconductor-carbon alloy layer is a single crystalline silicon carbide layer, the silicon-containing reactant gas can be 100% silane (SiH₄) and the carbon-containing reactant gas can be 50% ethelene (C₂H₄) with helium as the balance gas. The flow rate of 100% silane can be from 2 sccm to 30 sccm, and the flow rate of 50% ethelene can be from 2 sccm to 40 sccm.

If the single crystalline silicon-carbon alloy layer is a single crystalline silicon carbide layer and a single crystalline sapphire substrate having a (0001) surface orientation is employed, a single crystalline silicon carbide layer with a hexagonal crystal structure, i.e., in alpha phase, and a (0001) surface orientation can be epitaxially deposited. Thus, the first exemplary structure can be formed such that the single crystalline semiconductor-carbon alloy layer 120 is the single crystalline silicon carbide layer in alpha phase. If the single crystalline silicon-carbon alloy layer is a single crystalline silicon carbide layer a single crystalline sapphire substrate having a (1102) surface orientation is employed, a single crystalline silicon carbide layer with cubic crystal structure of the zinc blende type, i.e., in beta phase, and a (110) surface orientation can be epitaxially deposited. Thus, the second exemplary structure of FIG. 3 can be formed such that the single crystalline semiconductor-carbon alloy layer 220 is the single crystalline silicon carbide layer in beta phase.

The composition of the single crystalline semiconductor-carbon alloy layer, and correspondingly, the composition of the semiconductor-containing precursor and the carbon-containing precursor are selected to maintain a (0001) growth plane and a hexagonal crystal structure if the single crystalline semiconductor-carbon alloy layer is formed on a (0001) sapphire substrate Likewise, if the single crystalline semiconductor-carbon alloy layer is formed on a (1102) sapphire substrate, the composition of the semiconductor-containing precursor and the carbon-containing precursor are selected to maintain a (110) growth plane and a cubic crystal structure.

Once the deposition step is completed, the process chamber can be evacuated to a base pressure, and the temperature of the process chamber can be lowered to a temperature suitable for unloading of the first and/or second exemplary structure.

It is noted that, by reducing the deposition temperature or by otherwise providing inferior growth conditions, for example, by providing an ambient including a significant level of residual gases within a deposition chamber, the single crystalline semiconductor-carbon alloy layer 220 can be replaced with a polycrystalline semiconductor-carbon alloy layer having the same crystallographic alignment with underlying crystalline structures, while including grain boundaries between the various grains.

Samples of the first exemplary structure and the second exemplary structure have been formed and tested in the course of experiments leading to the instant invention employing the methods describe above. These samples have been subjected to various types of analysis including x-ray diffraction, secondary ion mass spectroscopy, and transmission electron microscopy.

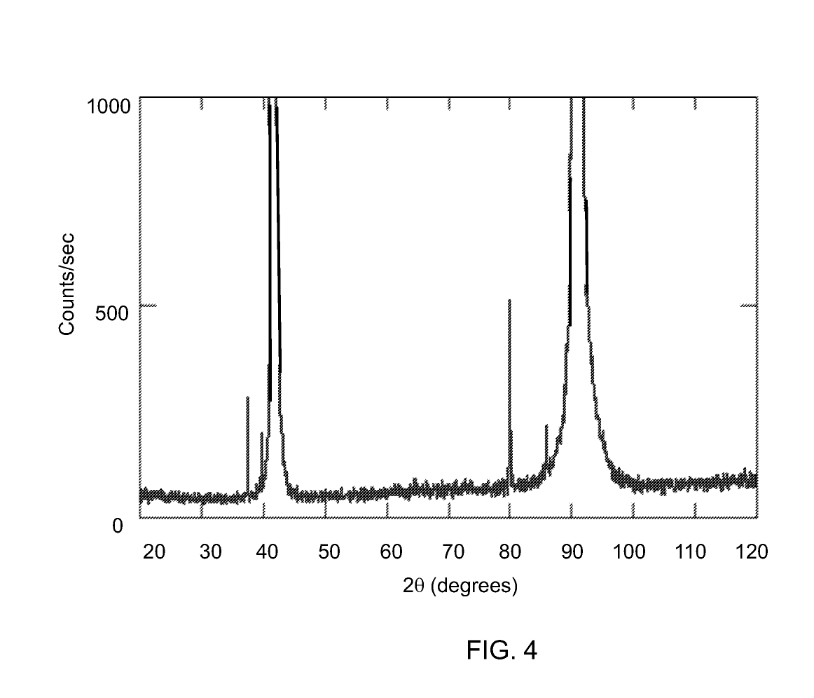

Referring to FIGS. 4-6, x-ray diffraction (XRD) data from a first sample having the first exemplary structure is shown before and after formation of a single crystalline silicon carbide layer in alpha phase, which corresponds to the single crystalline semiconductor-carbon alloy layer 120 of FIG. 2. Specifically, FIG. 4 is a graph showing x-ray diffraction data from a sapphire substrate having a (0001) surface orientation before deposition of the single crystalline silicon carbide layer. Each peak in the 2θ scan in FIG. 4 corresponds to a periodicity in the crystallographic planes involved in the scattering of the diffracted x-ray photons and present in the (0001) sapphire substrate.

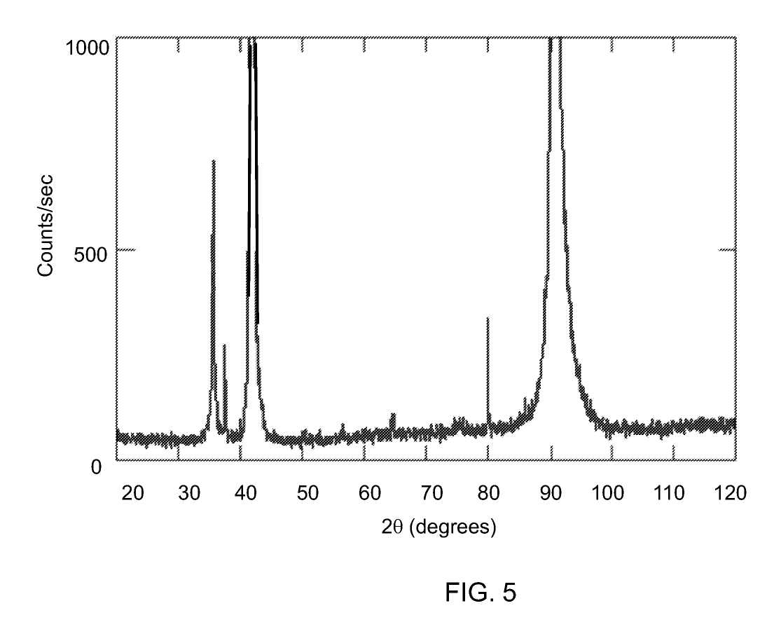

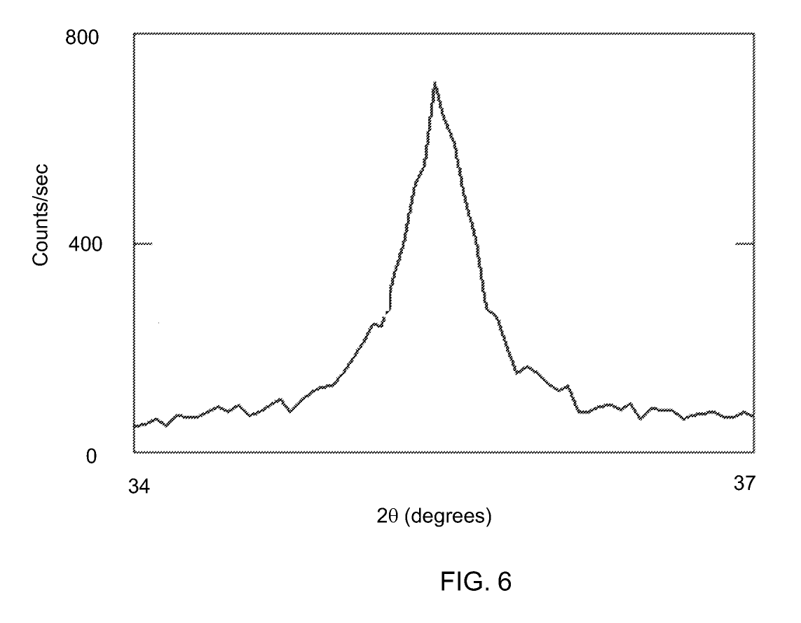

FIG. 5 is a graph of x-ray diffraction (XRD) data from the first sample after deposition of the single crystalline silicon carbide layer in alpha phase, which has a hexagonal crystal structure. The first sample is a stack of a single crystalline semiconductor-carbon alloy layer having a hexagonal crystal structure and a (0001) surface orientation and the underlying sapphire substrate having a (0001) surface orientation. FIG. 6 is a magnified graph of x-ray diffraction (XRD) data of FIG. 5 for the 2θ range from 34 degrees to 37 degrees. A prominent peak is present at the 2θ value of 35.5 degrees. This peak corresponds to a (0001) plane of the single crystalline silicon carbide layer in alpha phase. The full width at half maximum is about 0.273 degrees, which corresponds to an average domain size of at least 34 nm. The presence of the peak at the 2θ value of 35.5 degrees shows that the silicon carbide layer present in the first sample has a hexagonal crystal structure and alpha phase, and is oriented along the (0001) orientation, i.e., the surface of the silicon carbide layer is a (0001) surface.

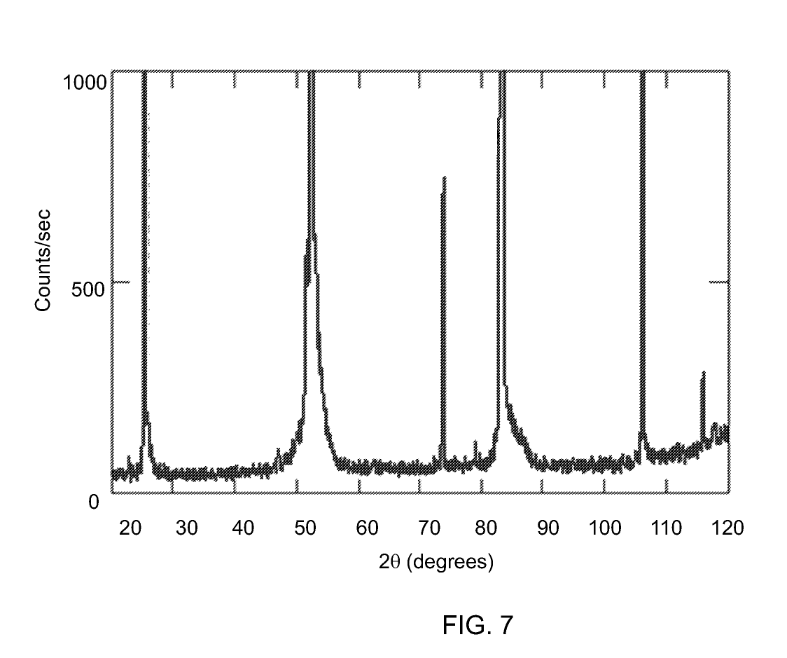

Referring to FIGS. 7-9, x-ray diffraction (XRD) data from a second sample having the second exemplary structure is shown before and after formation of a single crystalline silicon carbide layer in beta phase, which corresponds to the single crystalline semiconductor-carbon alloy layer 220 of FIG. 3. Specifically, FIG. 7 is a graph showing x-ray diffraction data from a sapphire substrate having a (1102) surface orientation before deposition of the single crystalline silicon carbide layer. Each peak in the 2θ scan in FIG. 7 corresponds to a periodicity in the crystallographic planes involved in the scattering of the diffracted x-ray photons and present in the (1102) sapphire substrate.

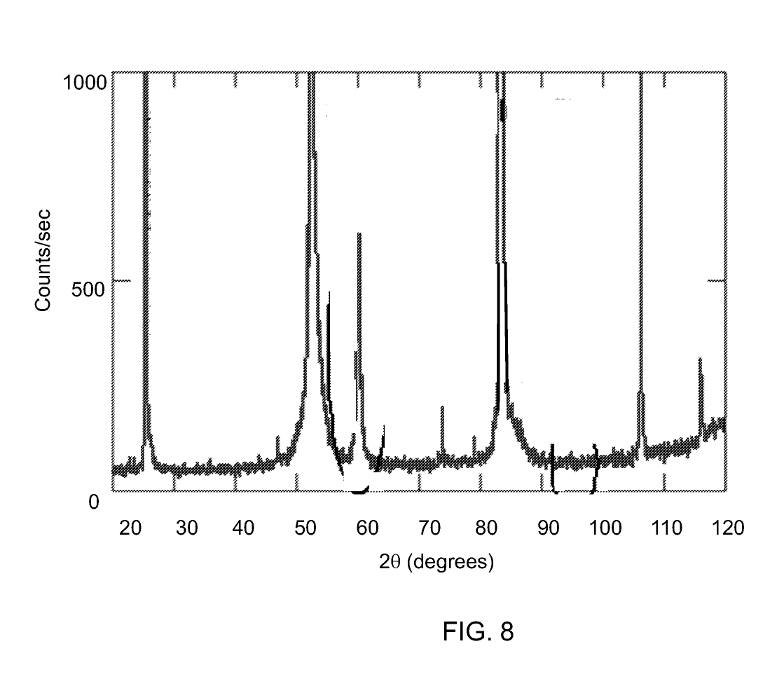

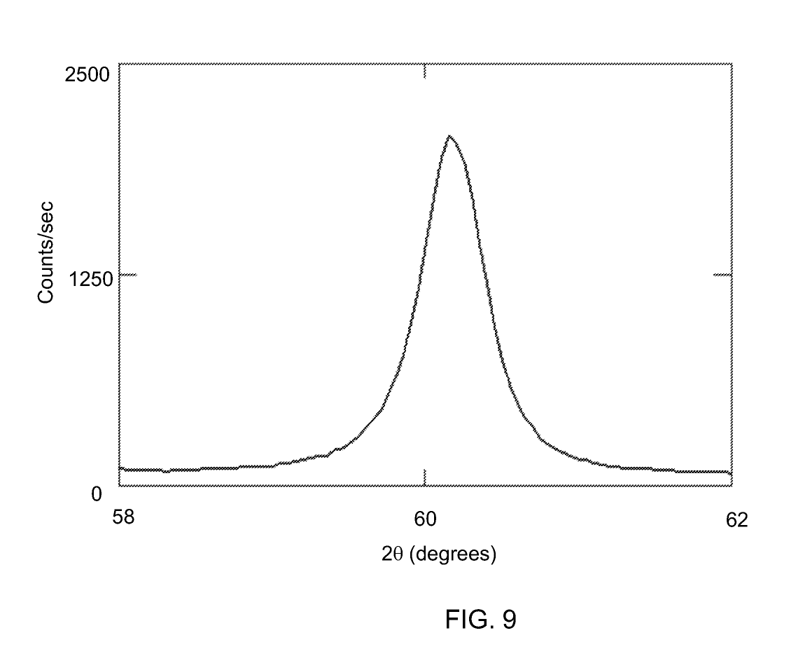

FIG. 8 is a graph of x-ray diffraction (XRD) data from the second sample after deposition of the single crystalline silicon carbide layer in alpha phase, which has a cubic crystal structure of zinc blende type. The second sample is a stack of a single crystalline semiconductor-carbon alloy layer having a cubic crystal structure and a (110) surface orientation and the underlying sapphire substrate having a (1102) surface orientation. FIG. 9 is a magnified graph of x-ray diffraction (XRD) data of FIG. 5 for the 2θ range from 58 degrees to 62 degrees. A prominent peak is present at the 2θ value of 61.1 degrees. This peak corresponds to a (110) plane of the single crystalline silicon carbide layer in alpha phase. The full width at half maximum in FIG. 9 corresponds to an average domain size of at least 20 nm. The presence of the peak at the 2θ value of 61.1 degrees shows that the silicon carbide layer present in the second sample has a cubic crystal structure and alpha phase, and is oriented along the (110) orientation, i.e., the surface of the silicon carbide layer is a (110) surface.

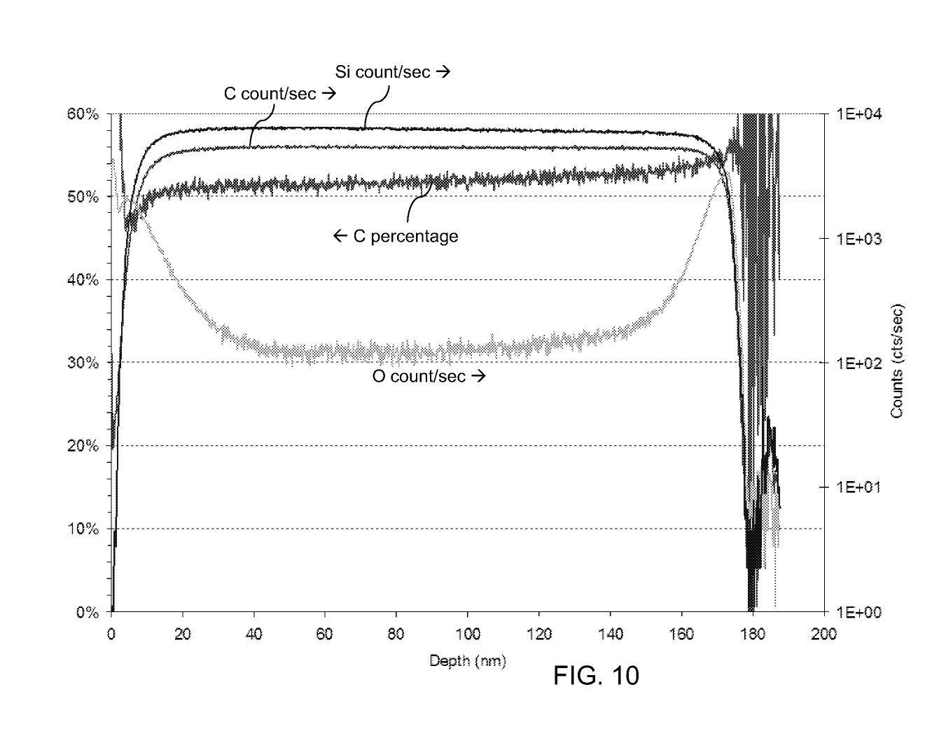

Referring to FIG. 10, a graph shows data from a secondary ion mass spectroscopy (SIMS) run on the first sample of FIGS. 5 and 6. As discussed above, the first sample included a stack of a sapphire substrate having a (0001) surface orientation and a single crystalline silicon carbide layer having a hexagonal crystal structure, having a (0001) surface orientation, and epitaxially deposited thereupon employing the methods described above. Silicon, carbon, and oxygen contents of the first sample was analyzed as a function of depth from the top surface of the sample, i.e., from the top surface of the single crystalline silicon carbide layer. The amount of detected silicon, the amount of detected carbon, and the amount of detected oxygen during the SIMS run are plotted on a log scale, which is provided on the right side vertical axis of the graph employing counts per second as the unit. Upon calibration of the sensitivity of the detector, the amount of detected silicon, the amount of detected carbon, and the amount of detected oxygen can be converted to atomic concentration. The atomic percentage of carbon thus calculated is also plotted on the same graph using the scale on the left side vertical axis of the graph. The SIMS data shows that the percentage of carbon in the single crystalline silicon carbide layer in the first sample is about 50%, showing that the single crystalline silicon carbide layer in the first sample is substantially stoichiometric, i.e., has a Si to C ratio of 1:1.

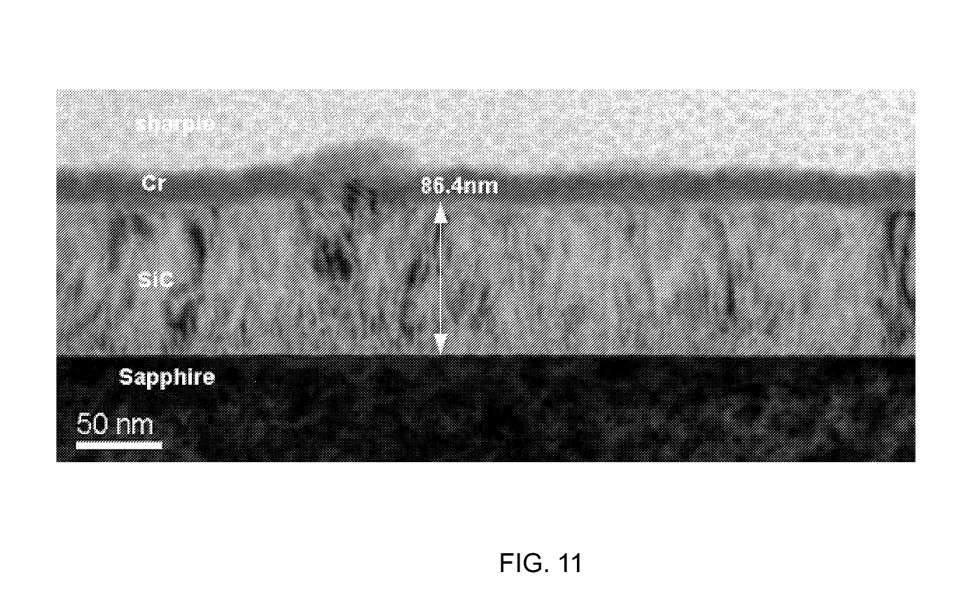

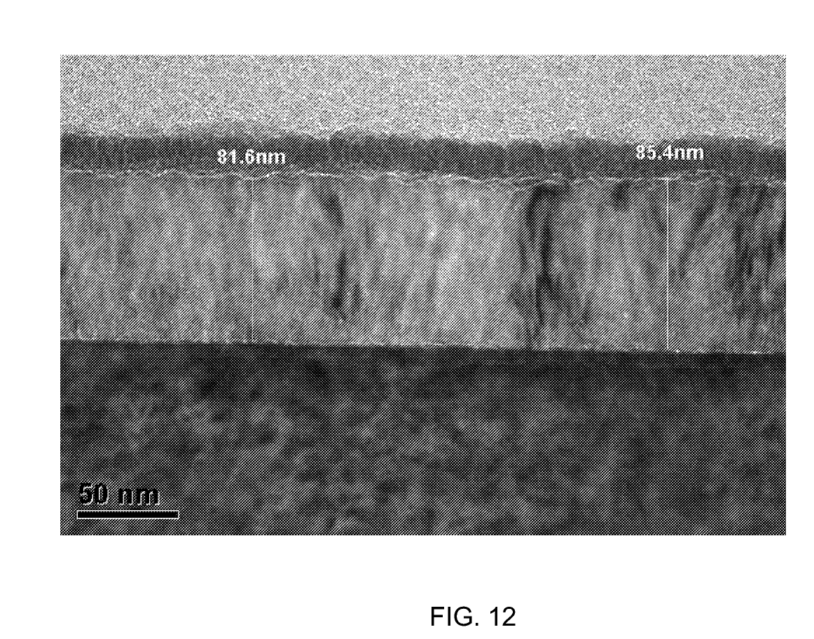

Referring to FIG. 11, a transmission electron microscopy (TEM) image of an area of the second sample is shown. The second sample includes a stack of a sapphire substrate having a surface orientation and a single crystalline semiconductor-carbon alloy layer having a hexagonal crystal structure and a (001) surface orientation. A chromium layer and a sharpie layer were added to the sample prior to preparation of the TEM sample in order to enhance the contrast of the TEM image. FIG. 12 shows a TEM image of another area of the second sample.

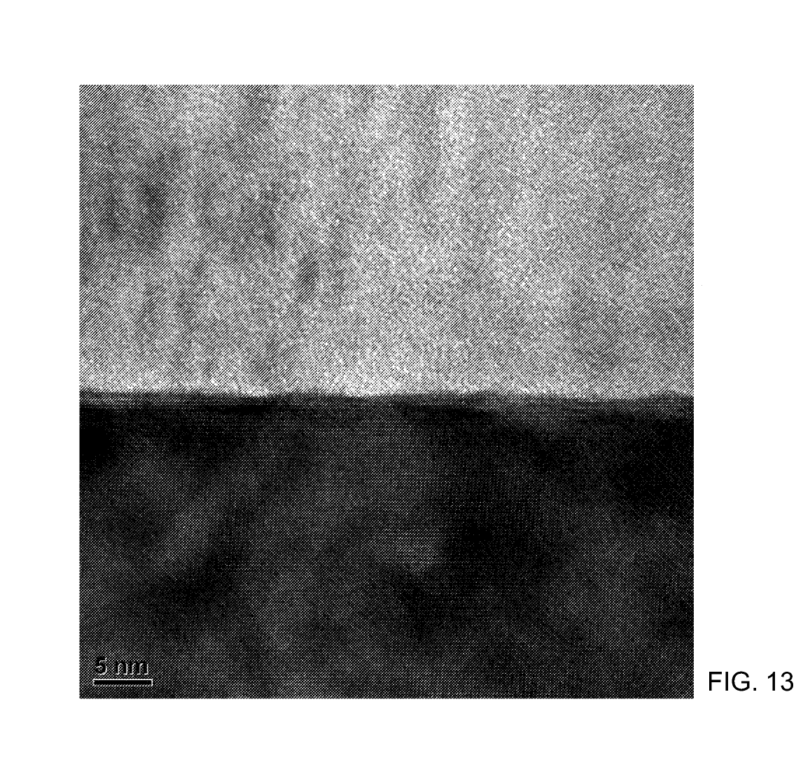

Referring to FIG. 13, a high magnification TEM image of an area of the second sample is shown. The high magnification TEM image shows a periodic pattern across the sapphire area (the dark area in the lower portion of the TEM image) and another periodic across the silicon carbide area (the light area in the upper portion of the TEM image).

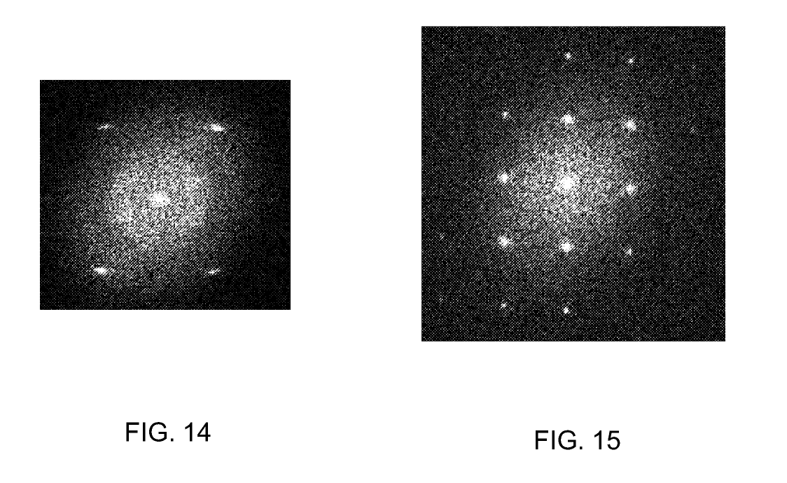

Referring to FIG. 14, a Fourier transformation image of the silicon carbide area of the high magnification transmission electron microscopy (TEM) image of FIG. 13 shows that the periodicity of the lattice within the plane of the high magnification TEM image of FIG. 13 has a square symmetry with a unit length of 0.24 nm. This is consistent with a single crystalline silicon carbide layer having a cubic structure and grown in a <110> direction with a corresponding (110) surface during growth. Thus, the Fourier transformation image of FIG. 14 verifies the x-ray diffraction data about the crystallographic orientation of the single crystalline silicon carbide layer.

Referring to FIG. 15, a Fourier transformation image of the sapphire area of the high magnification transmission electron microscopy (TEM) image of FIG. 13 shows that the periodicity of the lattice within the plane of the high magnification TEM image of FIG. 13 has a square symmetry with a unit length of 0.34 nm. This is consistent with a single crystalline sapphire substrate having a <1102> direction along the vertical direction, i.e., in the direction perpendicular to the interface between the sapphire substrate and the single crystalline silicon carbide layer.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A method of forming a semiconductor-carbon alloy layer on a sapphire substrate, said method comprising:
placing a sapphire substrate in a vacuum environment; and
providing a semiconductor-containing precursor and a carbon-containing precursor into said vacuum environment, wherein a single crystalline semiconductor-carbon alloy layer is epitaxially formed directly on a crystallographic surface of said sapphire substrate.

2. The method of claim 1, wherein an entirety of said sapphire substrate is single crystalline.

3. The method of claim 1, wherein said semiconductor-containing precursor includes silicon and said carbon-containing precursor includes carbon and hydrogen.

4. The method of claim 3, wherein said semiconductor-containing precursor is selected from SiH₄, Si₂H₆, SiH₃Cl, SiH₂Cl₂, SiHCl₃, and SiCl₄.

5. The method of claim 3, wherein said carbon-containing precursor is selected from C₂H₂, C₂H₄, C₂ₙ₋₂, and CₙH₂ₙ, wherein n is an integer greater than 2.

6. The method of claim 3, wherein said vacuum environment is provided by an ultrahigh vacuum chamber having a base pressure less than 1.0×10⁻⁶ Ton.

7. The method of claim 1, wherein said single crystalline semiconductor-carbon alloy layer is a single crystalline silicon-carbon alloy layer.

8. The method of claim 7, wherein said single crystalline semiconductor-carbon alloy layer has an atomic carbon concentration from 40% to 60%.

9. The method of claim 8, wherein said single crystalline semiconductor-carbon alloy layer is a single crystalline silicon carbide layer having a hexagonal or cubic crystal structure.

10. The method of claim 1, wherein the said semiconductor-carbon alloy layer includes at least one polycrystalline semiconductor-carbon alloy portion.

11. The method of claim 10, wherein said semiconductor-carbon alloy layer has an atomic carbon concentration from 40% to 60%.

12. The method of claim 11, wherein said semiconductor-carbon alloy layer includes a mixture of at least one polycrystalline silicon carbide portion having a hexagonal or cubic crystal structure.

13. The method of claim 1, wherein said single crystalline semiconductor-carbon alloy layer is deposited with a (0001) surface orientation and a hexagonal crystal structure directly on a (0001) plane of said sapphire substrate.

14. The method of claim 1, wherein said single crystalline semiconductor-carbon alloy layer is deposited with a (111) surface orientation and a cubic crystal structure directly on a (1102) plane of said sapphire substrate.

15. The method of claim 1, wherein said single crystalline semiconductor-carbon alloy layer is deposited at a temperature from 800° C. to 2,000° C.

16. A structure comprising a single crystalline semiconductor-carbon alloy layer located directly on a crystallographic surface of a sapphire substrate.

17. The structure of claim 16, wherein an entirety of said single crystalline semiconductor-carbon alloy layer is epitaxially aligned to a crystallographic lattice of said sapphire substrate.

18. The structure of claim 16, wherein an entirety of said sapphire substrate is single crystalline.

19. The structure of claim 16, wherein said single crystalline semiconductor-carbon alloy layer is a single crystalline silicon-carbon alloy layer.

20. The structure of claim 19, wherein said single crystalline semiconductor-carbon alloy layer has an atomic carbon concentration from 40% to 60%.

21. The structure of claim 20, wherein said single crystalline semiconductor-carbon alloy layer is a single crystalline silicon carbide layer having a hexagonal or cubic crystal structure.

22. The structure of claim 16, wherein said single crystalline semiconductor-carbon alloy layer has a hexagonal crystal structure, wherein a (0001) surface of said single crystalline semiconductor-carbon alloy layer contacts a (0001) plane of said sapphire substrate at an interface.

23. The structure of claim 16, wherein said single crystalline semiconductor-carbon alloy layer has a cubic crystal structure, wherein a (111) surface of said single crystalline semiconductor-carbon alloy layer contacts a (1102) plane of said sapphire substrate at an interface.

24. A structure comprising at least one polycrystalline semiconductor-carbon alloy layer located directly on a crystallographic surface of a sapphire substrate.

25. The structure of claim 24, wherein grains of said at least one polycrystalline semiconductor-carbon alloy portion has a hexagonal crystal structure, wherein a (0001) surface of said at least one polycrystalline semiconductor-carbon alloy portion contacts a (0001) plane of said sapphire substrate at an interface.
